(19) United States
(12) Patent Application Publication
(10) Pub. No.: US 2005/0083067 A1
(43) Pub. Date: Apr. 21, 2005

(54) Coded multi-frequency transmitter and receiver for testing multi-conductor cables

(76) Inventor: Emuel Paul Kirbas, Dallas, GA (US)

Correspondence Address: Mr. Emuel Paul Kirbas, 209 Mt. Laurel Drive, Dallas, GA, 30132, US

(21) Appl. No.: 10/943,390

(22) Filed: Sep. 17, 2004

Related U.S. Application Data
(60) Provisional application No. 60/505,192, filed on Sep. 23, 2003.

(51) Int. Cl. H04B 3/46; G01R 31/02

(52) U.S. Cl. 324/539

(57) ABSTRACT

A portable hand-held apparatus for testing the presence of individual conductors in multi-conductor cables of varying types and sizes. The apparatus includes a variable-frequency scanning transmitter for connection to one end of a cable under test, and a local or remote receiver connected to the opposite end of the cable. The transmitter generates sequential frequencies to transmit signals sequentially through each of the conductors to the receiver. The transmitted frequencies contain embedded codes that are directed to each conductor containing the same position in the cable as that of the embedded code. A Lock Detection Marker pulse is generated that synchronizes the remote elements of the receiver with the sequential function of the transmitter, identifies which conductor in sequence the receiver is monitoring for cable faults, and records the test results on visual displays, affording a high degree of speed and accuracy over long transmission distances.

### REFERENCE CITED

U.S. Patent Documents

| | | | |
|---|---|---|---|
| 2,904,750 | Sep. 15, 1959 | Gargani | 324/539 |
| 3,492,571 | Jan. 27, 1970 | Desler | 324/73 |
| 3,681,686 | Aug. 1, 1972 | Connally | 324/66 |
| 3,699,438 | Oct. 17, 1972 | Webb | 324/66 |
| 3,902,026 | Aug. 26, 1975 | Rogers | 179/175.3A |
| 4,282,479 | Aug. 4, 1981 | Deboo | 324/540 |
| 4,384,249 | May 17, 1983 | Medina | 324/540 |
| 4,418,312 | Nov. 29, 1983 | Figler | 324/540 |
| 4,445,086 | Apr. 24, 1984 | Bulatao | 324/66 |
| 4,772,845 | Sep. 20, 1988 | Scott | 324/66 |
| 4,901,004 | Feb. 13, 1990 | King | 324/66 |
| 4,937,519 | Jun. 26, 1990 | Fields | 324/66 |
| 5,027,074 | Jun. 25, 1991 | Haferstat | 324/539 |
| 5,155,440 | Oct. 13, 1992 | Huag | 324/539 |
| 5,280,251 | Jan. 18, 1994 | Strangio | 324/539 |
| 5,627,474 | May 6, 1997 | Baudisch | 324/539 |
| 6,466,885 | Oct. 15, 2002 | Miller | 702/116 |

### RELATED APPLICATIONS

This application claims the benefit under 35 U.S.C. 119(e) of U.S. Provisional Application Ser. No. 60/505,192 filed Sep. 23, 2003.

### FIELD OF THE INVENTION

The invention relates to portable electrical testing apparatus and, more specifically, to cable testers for automatically testing and identifying individual conductors in multi-conductor cables by applying sequentially varying frequency signals containing embedded codes to the cable under test, and processing the received signals at local or remote locations.

### DESCRIPTION OF RELATED ART

Information flow is a vital part of our society and cables play a very important role as a medium for transmission. Multi-conductor cables are used in telephone lines, Local and Wide Area Networks, communication pathways, security networks, and in a host of other critical applications. Complexity and cost of project equipment increase the need of assurance that cables are installed and terminated properly without faults arising on the conductors. Cable conductors are tested for faults during initial acceptance testing. Cables accepted for operation but not tested for faults result in damaged equipment, rising project costs and delays in project startup.

Cable ends are terminated in appropriate connectors and are typically located remote from each other. A cable installer attaches each pin of the connector to a corresponding conductor in the cable, usually by hand soldering or by other mechanical means, thus possibly producing errors in cable connections, thereby exposing expensive equipment to electrical faults during normal operations. Prior to connection to intended equipment, cables undergo various tests to determine the viability of the transmission link. A variety of cable testers have been proposed in prior art that incorporate various design technologies. Simple testers such as common off-the-shelf volt-ohm meters have been the standard for many years. Such testers are, however, slow, labor intensive, cumbersome, error prone and tedious in today's high-tech society. Some testers yield erroneous measurement results owing to the design methodology of resistors as the sensing medium. Some testers incorporate Light Emitting Diodes, LED, as displays in series with each conductor for visual fault indication, requiring two operators, one at each end of the cable. Other various and sundry methods are used.

The following indicate several patents that exhibit severe limitations:
1. Huag U.S. Pat. No. 5,155,440: Contains three sets of voltage references, faults are determined by variations in the references voltages visible on the LEDs. Operator must interpret the intensity of the lamps as to the nature of the fault.
2. Bulatao U.S. Pat. No. 4,445,086: Requires a separate ground return path conductor not to be included in the cable, eliminating testing of cables where no conductor within the cable is available for grounding.
3. Gargani U.S. Pat. No. 2,904,750: Sequentially advances the position of three stepping relays to connect selected conductors for test; slow and prone to mechanical failures.

Most of today's high-end cable testers employ voltage or current techniques as the measurable parameters, signal frequencies that uniquely identify each conductor in the cable. Each has advantages and disadvantages, particularly when called upon to test long transmission lines that present differing parameters. Haferstat U.S. Pat. No. 5,027,074 contains several design concerns as follows:
1. Transmitter connector pins are not synchronized to receiver connector pins, producing errors in transmission. In stating an example in said patent, receiver conductor errors from the transmitter as indicated on a display, Haferstat states the following: “Found-1,2,3,5,4,6,7,8,9-on a 9 pin cable, lines 4 and 5 crossed.” This is fairly simple to analyze as transmitter pin 4 is crossed to receiver pin 5 and T5 crossed to R4, all other pins connected straight-through correctly. But if the following error should occur: “1,2,5,4,3,6,9,8,7” it is difficult to determine accurately what transmitter pins produced the crossed 5,3,9,7 conductors at the receiver, all other conductors correctly wired.
2. The design does not perform a transmitter self-test for shorts in its connected end of the cable. If a short exists, on say transmitter pins 4 and 5 and no conductors are connected from the shorted pins to the receiver, the receiver may be able to continue the sequence but the display will read “open” for both pins 4 and 5, whereas a “short” is at the transmitter end.
3. The design has no provision for testing the shield in shielded cables.
4. The patent requires cables to be tested to be greater than three (3) conductors.
5. The design tests only one cable type at a time by insertion into the enclosures printed circuit boards containing the proper mating connector. The invention requires different printed circuit boards for other input cable types and sizes.
6. The design does not function as described when short circuits are encountered. Each conductor connected at the receiver has a resistor tied to ground potential, but at the transmitter no grounding resistor is used, therefore the conductor is tied directly to the transmitter output. A pulse applied on conductor 1 and a short placed across conductor 1 to conductor 2 cannot be measured correctly as stated. To confirm this, a BCD-Decimal Decoder CD4028B was connected to 5.0 volt VCC supply as specified on Page 13 of said patent, reference number 38. A resistor of 10 k ohms was placed on the output of pins 1 and 2 and tied to ground potential. An oscilloscope was connected from pin 1 to ground and viewed a 5-volt level with no short placed. A short was then placed from pin I to pin 2, resulting in the loss of the signal on pin 1 to a level of 0.5 volts, which is not of sufficient magnitude to switch receiver shift register CD4021B, reference 52, into a high state. The data sheet of Logic Family 4000 guarantees a level of 3.5 volts for V(ih) in the input mode to switch to the Logic 1 output state. The display in the receiver will then read, “no signal on pins 1 and 2,” indicating open circuits whereas the proper reading should be, “pin 1 shorted to pin 2.”

This invention eliminates all the disadvantages found in U.S. Pat. No. 5,027,074 and provides an improvement in all prior art cable testers. The invention contains: no reference voltages; proper placement of ground return resistors; no mechanical stepping relays; transmitter synchronized with the receiver; performs transmitter self-test for short circuits; provision for testing shielded cables; requires two conductors minimum for testing; functions correctly under short circuit conditions; and is simultaneously capable of testing multiple cables individually at remote locations.

### SUMMARY OF THE INVENTION

In accordance with the present invention, means are provided for an improved method for testing various types and sizes of multi-conductor cables. The invention may contain one or more permanently affixed connectors, each of which corresponds to a particular class of cables to be tested. The invention comprises of a transmitter capable of generating variable frequency signals into affixed output connectors that are connected to one end of each cable, and a receiver capable of receiving and processing said signals at a local or remote location, connected to the other end of each cable through affixed connectors. A minimum of two conductors is required for a cable to be tested as one of the conductors serves as a ground return path for the signal impressed on the other conductor. Both transmitter and receiver are powered by an external power source in conjunction with an internal battery that is monitored and charged by a power management system for minimum power consumption. Each power source can supply power to the system independent of the other. LCD and/or LED displays are used for visual indication of wiring faults in the cables under test and keypads contain input devices to control the varied functions of the invention. The invention is constructed with, but not limited to, Complimentary Metal Oxide Semiconductors (CMOS) Integrated Circuit elements, and Complex Programmable Logic Devices (CLPD), programmed using Very High Speed Integrated Descriptive Language (VHDL) computer software. All devices are mounted on printed circuit boards.

A cable for test is terminated with connectors at both ends of the cable suitable for connection to connectors affixed to both transmitter and receiver. The transmitter sequentially generates variable frequency signals with embedded codes, directs each signal to corresponding connector pins with position numbers as that of the embedded codes and hence to conductor numbers in the cable as that of the pin numbers. Improvements then, in the apparatus over prior art, sequentially applies particular frequencies with particular codes to particular connector pins connected to particular conductors in the cable. The frequency signal arriving in sequence at each receiver connector pin is directly related to the number of the transmitter pin energized. Through the transmission medium, the receiver processes the transmitted frequency signals in sequence and establishes the correctness of each of its connector pins as having the same embedded code number relationship as that in the embedded transmitted signals. Correct continuity is established when the embedded frequency codes are matched, incorrect continuity is established when the codes are mismatched.

The receiver detects and displays correct conductor terminations in the cable as well as cable faults of shorts, open or grounds, crosses, split pairs, and rolls, and to do so over long transmission distances with a high degree of accuracy. The results of the test are visibly recorded on LCD and/or LED displays.

### BRIEF DESCRIPTION OF THE DRAWING

FIG. 1 is a view of transmitter, receiver and connected multi-conductor cable.

FIG. 2 is a partial schematic drawing of transmitter frequency code generation.

FIG. 3 is a partial schematic drawing, Sheet 1 of 3, of receiver signal processing.

FIG. 4 is a partial schematic drawing, Sheet 2 of 3, of receiver signal processing.

FIG. 5 is a partial schematic drawing, Sheet 3 of 3, of receiver signal processing.

### DETAILED DESCRIPTION OF THE PREFERRED EMBODIMENT

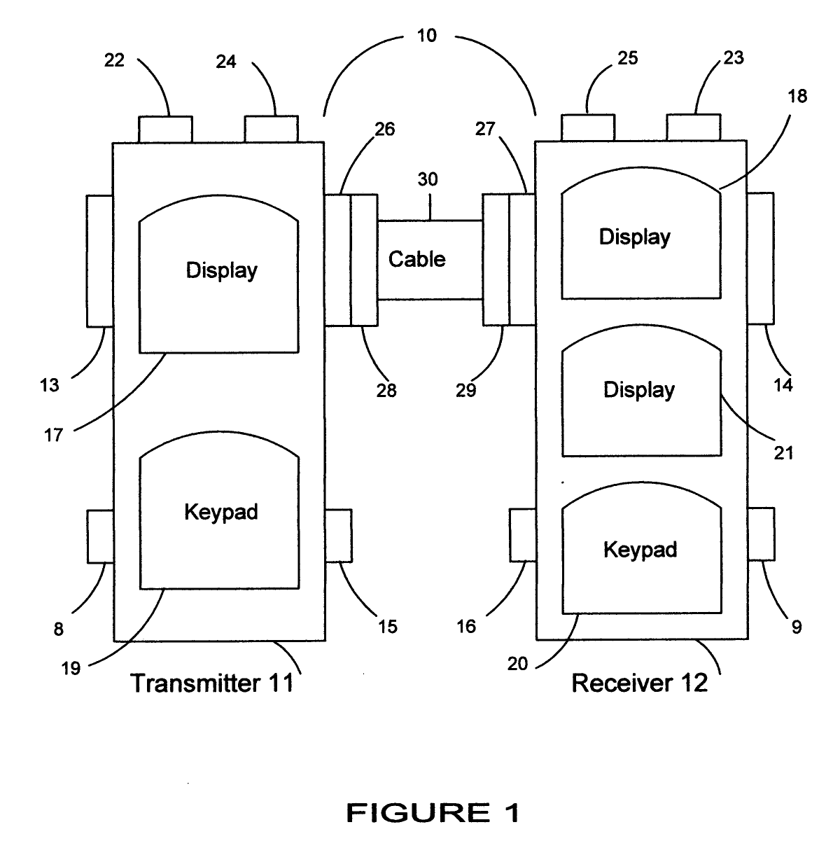

Referring now to FIG. 1 that illustrates a Cable Testing 10 system consisting of Transmitter 11 and Receiver 12 in accordance with the invention, to test conductors in multi-conductor cables. One test Cable 30 with affixed connectors at each end is illustrated for clarity and may be extended to include connectors corresponding to several classes and sizes of cables, such as, but not limited to:
1. Telephone
2. Axial
3. Fiber Optic
4. Multi-conductor

Connectors 26 and 27 affixed to Transmitter 11 and Receiver 12 respectively can be of size (p) corresponding to the maximum size of Cable 30 for test. Commercially available external cable adapters and gender changers, sized from (p) to (p-a) connector pins, may be used to test other commercially available cables. For further discussion, one embodiment of the invention of Transmitter 11 has been designed, built and tested in accordance with the invention with one subminiature multi-conductor connector of size p=68 for affixed Connectors 26 and 27. The value of (p) is limited only by the size and number of CPLD IC components required for larger designs.

Cable Tester 10 can be powered by an external power source through Connectors 15 and 16 of Transmitter 11 and Receiver 12 respectively. The designed Transmitter 11 can test up to 68 test points for the multi-conductor Cable 30. A minimum of two (2) conductors are required for testing as one of the two conductors serves as a ground return path for the signal impressed upon the other conductor. In a typical testing mode, Cable 30, with affixed Connectors 28 and 29, are connected to cable Connectors 26 and 27 of Transmitter 11 and Receiver 12 respectively, and a Transmitter 11 self-test is performed via control inputs from the Transmitter 11 Keypad 19. This test is required for under certain conductor configurations, a short circuit located at Transmitter 11 end of Cable 30, with no conductors attached to the connector pins to Receiver 12, will be correctly recorded on Transmitter 11 Display 17 indicating a “short” circuit condition but will not be properly recorded on Receiver 12 Display 21 during normal cable testing, reading “open circuit” instead of “short circuit.” Affixed Connectors 8 and 9 are computer ports for general testing, maintenance and reprogramming functions. As shown, affixed Connectors 13 and 14 may be included in another embodiment of the present invention for telephone cable inputs, as well as Connectors 22 and 23 for fiber optic and Connectors 24 and 25 for testing axial type cables, each containing (n) pins. Receiver Display 18 and Keypad 20 to be discussed below.

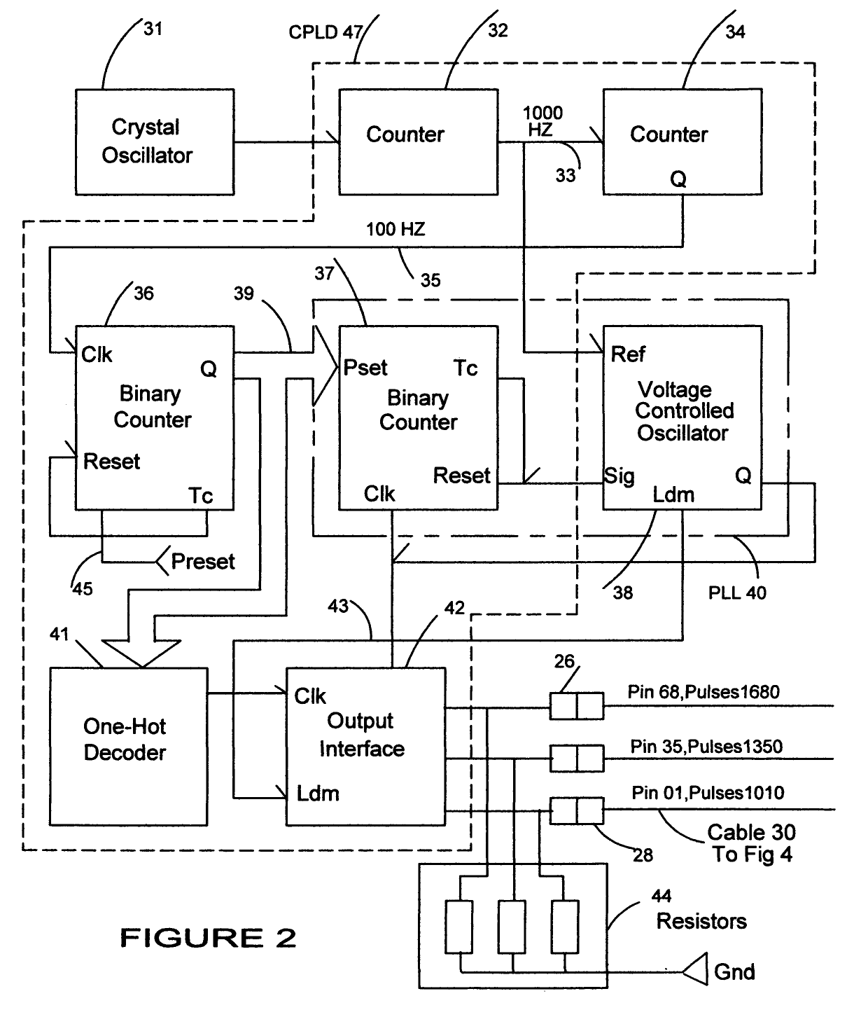

Referring now to FIG. 2 during test of Cable 30, Transmitter 11 FIG. 1 receives a clock frequency from Crystal Oscillator 3 land Counter 32 divides the oscillations to obtain a 1,000 Hz Frequency Reference 33 signal that is further divided by Counter 34 to obtain a 100 Hz (10 millisecond period) Scan Frequency 35 signal. The Frequency Reference 33 signal is routed to Variable Frequency Oscillator, VCO 38, reference input pin. Binary Down Counter 36, Preset 45 set at binary 10101000 (decimal 168), accepts the Scan Frequency 35 signal as a clock input and decrements the counter every 10 ms. Outputs on Binary Bus 39 start from the binary value of 10101000 (decimal 168), decremented in steps of decimal one (1), sequentially down to 01100100 (decimal 101), repeating the cycle by output TC, terminal count, going high and resetting Counter 36.

The Binary Bus 39 decimal values are later converted to frequency signals that will be sequentially impressed upon each pin of affixed Connector 26 FIG. 1 and, hence, sequentially on each conductor of Cable 30. The range of frequencies generated contains embedded codes EC, of (e down-to 01), that will identify sequential frequencies SF, of (f down-to 101,000), impressed upon particular connector pins Pin, of (p down-to 01) and hence on particular conductors C, of (c down-to 01). The embedded codes are identified at the 2nd and 1st bit positions of the decimal value of the binary codes on Binary Bus 39. Therefore SF 168,000 down-to 101,000 Hz will be generated, each frequency proceeded by an LDM 43 synchronizing pulse, and sequentially impressed upon Pin 68 down-to 01 of Connector 26, the 5th and 4th bit positions being the most- and least-significant decimal values of the pin numbers and conductor numbers. Therefore at the high end, SF 168,000 is applied to Pin 68 containing EC 68; sequentially the mid-range connector Pin 35 will receive SF 135,000 Hz containing EC 35; and the last connector pin will receive SF 101,000 Hz with EC 01 on Pin 01.

Binary Bus 39 values are routed to the preset pin of Binary Down Counter 37 and clocked by the output of VCO 38. Counter 37 begins to count and produces a series of pulses at a particular binary value on its preset pin for 10 milliseconds, continually resetting and repeating as TC terminal goes high. Therefore, each binary value on the preset pin is sequentially counted in like manner for 10 ms. The sequential outputs of TC are routed to the signal pin of VCO 38 where they are compared with the Frequency Reference 33 signal from Counter 32. This combination comprises a Phase Lock Loop, PLL 40, that produces an error signal to drive the output of VCO 38 to equal the value of the Frequency Reference 33 signal times the values of the TC pulses, (1000×168), hence SF 168,000 down-to 101,000 Hz are generated.

Binary Bus 39 values are also routed to the 8-to-68 One-Hot Decoder 41 that sequentially selects an output pin on Connector 26 to be energized. Hence Pin 68 will be selected if the code on Binary Bus 39 is decimal 168 that contains EC 68 in the 2nd and 1st bit positions. The Output Interface 42 controls the selection of a particular connector pin to be energized with a particular frequency signal generated by VCO 38 and inserts the Lock Detection Market LDM 43, that precedes each of the sequential transmitted frequencies. LDM 43 is a short pulse generated by VCO 38 to give indication that the sequentially generated frequencies have been established and are stable. The LDM 43 pulse becomes very important in the design of the receiver as it establishes synchronism between frequency transmission and receiver reception and processing, synchronizing Transmitter 11 scan times with Receiver 12 FIG. 1 scan times.

Resistor Bank 44 contains resistors attached to each pin in Connector 26 and, in conjunction with Cable 30 conductors, establish a ground return path for transmitted signals. In a 2-conductor Cable 30 for test and Pin 02 energized, the ground return path is on Pin 01 back to Transmitter 11. Pin 01 is not the pin energized with the signal and is held at high input impedance in the input mode. If Pin 01 is energized, held at low output impedance in the output mode, then Pin 02 is the return path at high input impedance, allowing Resistors 44 to conduct return signals to ground potential. Thus, a common ground reference is established between power supplies of both Transmitter 11 and Receiver 12, critical to the proper operation of the apparatus and to all cable testers with remote functions. Haferstat, in U.S. Pat. No. 5,027,074, fails to furnish ground return resistors at the transmitter connector pin locations, and also fails to incorporate proper transmitter output characteristics of high input impedance in the input mode. Two conductors in Cable 30 are the minimum required for testing cables. CPLD 47 includes the major software designed functions.

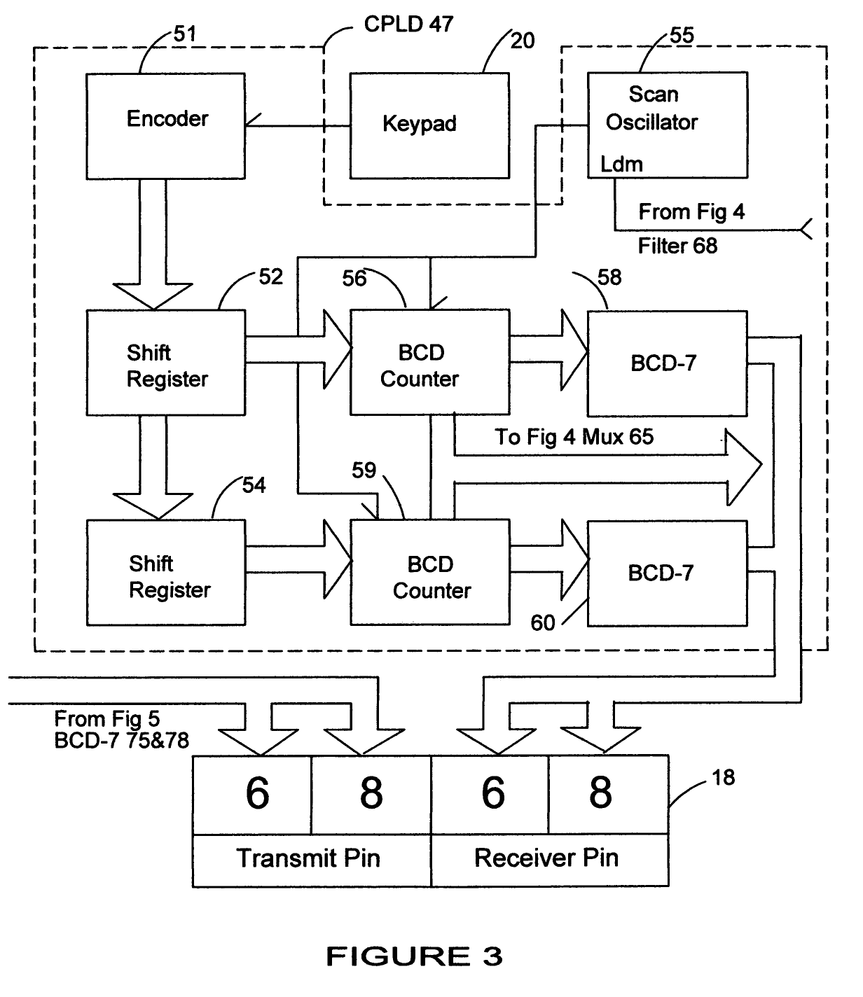

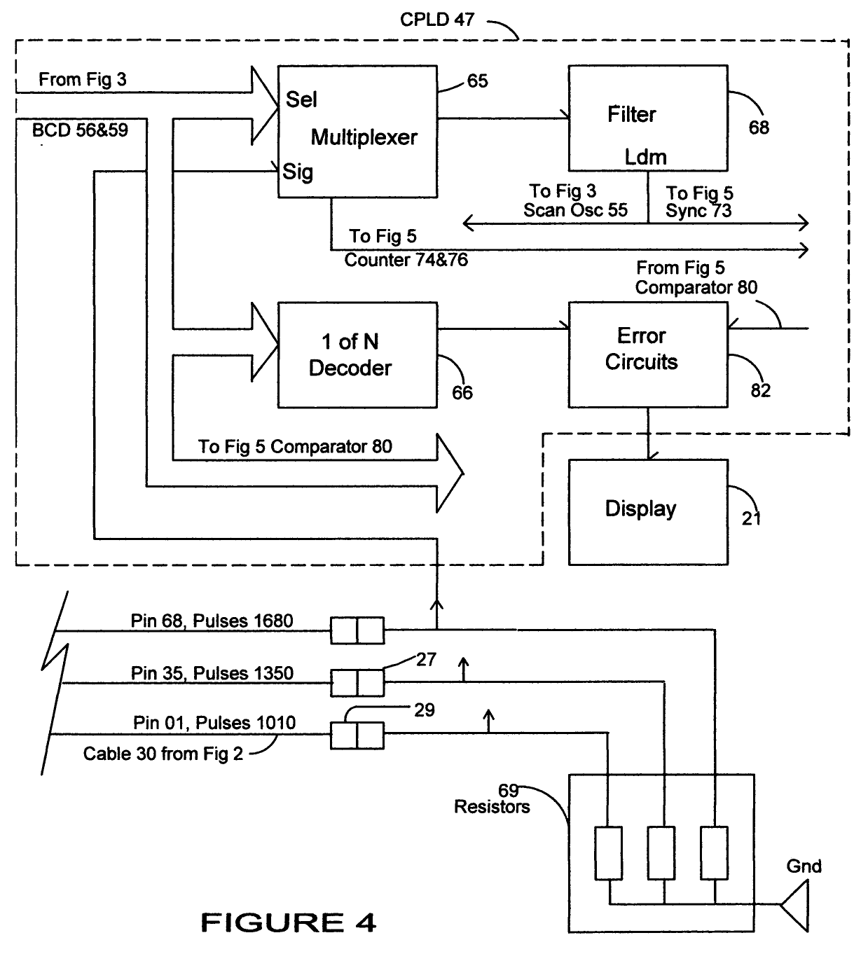

Referring now to FIG. 3, the number of cable conductors under test is inputted through Receiver 12 Keypad 20 FIG. 1, put in BCD format by Encoder 51 and routed to Shift Registers 52 and 54 that store the unit and tens digit if required, respectively in the conductor number. These values are routed to the preset pin of BCD Counters 56 and 59 whose outputs now contain Binary 0100 and 0100, decimal number 6 and 8, EC 6 and 8, and in turn is routed to BCD-7 Decoders 58 and 60. Receiver Display 18 FIGS. 1&3 visually indicates number 68 for Cable 30 FIG. 2. During test operations, Counters 56 and 59 will clock down from 68 to 01 by Scan Oscillators 55, receiving LDM 43 signals from Filter 68 FIG. 4, thereby indicating every conductor in sequence to be tested. Receiver Pin section of Receiver Display 18 represents Receiver 11 pins monitored for signals received, hence visual indication of 68-68 would mean, “Transmitter Pin 68 connected to Receiver Pin 68” (68 yet to be discussed with Transmitter 11). Conductor numbers connected to Transmitter 11 sequential pin numbers are the preferred sequence; Receiver 12 pin numbers and connected conductors are the variable sequence. Clock Oscillators 55 afford a choice of fast mode via LDM43 pulses, slow, or step modes of sequence scanning. The outputs of BCD Counters 56 and 59 are also routed to Multiplexer 65 FIG. 4 for further processing. CPLD 47 includes the major software designed functions.

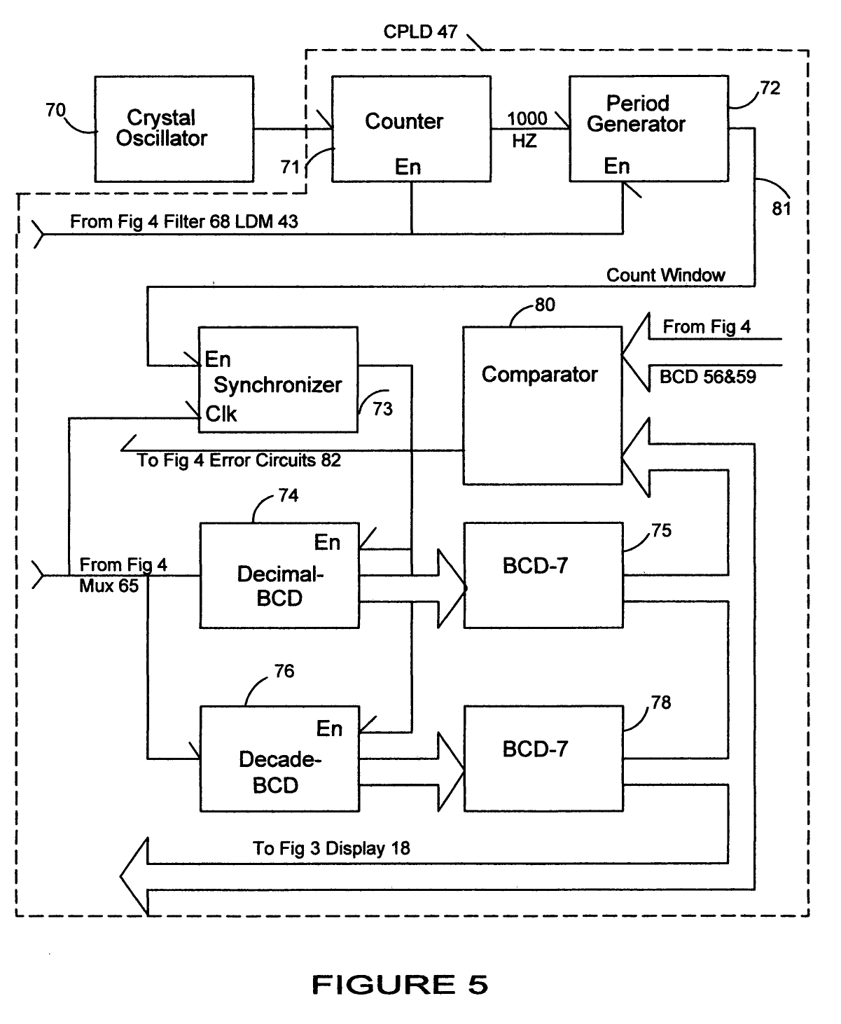

Referring now to FIG. 4, multi-conductor Cable 30, affixed to Connector 29 and connected to Receiver 12 affixed Connector 27, inputs received Transmitter 11 FIG. 2 signals to Multiplexer 65, with inputs from Counters 56 and 59 FIG. 3 containing EC 68, impressed upon the select pin. This select feature, in conjunction with 1-of-n Decoder 66, allows only the conductor on Pin 68 to be monitored with respect to transmitted frequencies and embedded codes, with all other energized conductors in parallel with Pin 68 routed to Error Circuits 82, then to Display 21 FIG. 1 indicating possible short circuits in Cable 30. The output of Multiplexer 65, containing a 1680 signal (168,000 Hz×10 ms duration) with synchronizing LDM 43 pulse, is routed to Counters 74 and 76 FIG. 5 and also through low pass Filter 68 to obtain the LDM 43 signal to both Scan Oscillator 55 FIG. 3 and to Synchronizer 73 FIG. 5. BCD 56 and 59 are also routed to Comparator 80 FIG. 5. Resistor Bank 69 is required for the ground return path back to Transmitter 11. CPLD 47 includes the major software designed functions.

Referring now to FIG. 5, Crystal Oscillator 70 is routed to Counter 71 that divides to obtain a 1,000 Hz signal that in turn is routed to Period Generator 72 to obtain a one-shot pulse or Count Window 81 of 1 ms. This pulse is routed to Synchronizer 73 that synchronizes the rising pulse of Count Window 81 with a rising pulse of LDM 43 signal from Filter 68 FIG. 4, and is clocked with pulses from Multiplexer 65 FIG. 4. The output from Synchronizer 73 is routed to Decimal-to-BCD Counter 74 and to Decade-to-BCD Counter 76 enable pins with frequency input pulses to be counted as the clock input, thereby enabling counting only during Count Window 81, not loosing nor gaining one pulse of the input signal.

Decimal-to-BCD 74 and Decade-to-BCD 76 each count up to 168 pulses, (168,000×0.001), outputting BCD 1000 or decimal 8, and BCD 0110 or decimal 6, respectively. These codes are routed to BCD-7 Decoders 75 and 78 and in turn routed to Transmitter Pin section of Receiver Display 18 FIG. 3 that visually indicate the embedded code that uniquely identifies the input signal, hence the frequency generated in Transmitter 1 FIG. 1. The combining of Receiver Pin section with Transmitter Pin section in Receiver Display 18 FIG. 3 yields a visual indication of 68-68. This may be read as: Transmitter 11 Pin 68, with SF 168,000 Hz containing EC 68 on Pin 68 and hence C 68, is received at Receiver 12 Pin 68 on C 68 and hence Pin 68 containing EC 68 with SF 168,000 Hz. Readings other than straight-through connections are to be considered errors, whether intentional or unintentional.

Receiver Display 18 FIG. 3 basic visual indications may be displayed and interpreted as, but not limited to, the following:
1. 68-68 would read as, “Transmitter 11 Pin 68 connected to Receiver 12 Pin 68, correct straight-through continuity connection.”
2. 67-68 would read as, “Transmitter 11 Pin 67 connected to Receiver 12 Pin 68, a crossed wire.”
3. 67-68 and simultaneously Display 21 FIG. 1 indicating 19, would read as, “Transmitter 11 Pin 67 connected to Receiver 12 Pin 68, crossed and either (a). shorted to Pin 19, or (b). split pair to Pin 19.”
4. 68-67 and sequentially 67-68 would read as, “Transmitter 11 Pin 68 connected to Receiver 12 Pin 67, and Transmitter 11 Pin 67 connected to Receiver 12 Pin 68, a roll.”
5. 00-68 would read as, “Transmitter 11 not connected to Receiver 12 Pin 68, either (a). open circuit at Pin 68 or (b). grounded conductor at Pin 68.”
6. 00-68 and simultaneously Display 21 FIG. 1 indicating 19, would read as, “Transmitter 11 not connected to Receiver 12 Pin 68, either (a). open circuit at Pin 68 or (b). grounded conductor at Pin 68; also Pin 68 shorted to Pin 19.”

Both Decoders 75 and 78 are routed to Comparator 80 where they are compared with Counters 56 and 59 FIG. 4. Any Receiver 12 Display 18 mismatch such as 68-67 will generate an error signal in Error Circuits 82 FIG. 4, stop Receiver 12 scanning and remain in that mode until acknowledged by operator Keyboard 20 FIG. 1 input, at which time scanning is resumed until the multi-conductor Cable 30 FIG. 1 is completely tested. CPLD 47 indicates the major software designed functions.

Accuracy and transmission distance contribute to the improvements and advances in design over previous art. Under test, a communications grade shielded copper cable transmitted 2500 feet with an applied 3.3 volts, SF 168,000 Hz signal, with a total loss in signal amplitude of 0.12 volts. The minimum signal amplitude at the input of a CPLD gate is approximately 0.8 volts, theoretically translating to a conservative upper limit of transmission distance greater than 5 miles.

A modified embodiment of the apparatus than that described above to increase the accuracy of the invention is to modify Counter 32 FIG. 2 to output 1004 instead of 1000 as described. This translates into SF of 168,672 Hertz down-to 101,404 Hertz instead of 168,000 down-to 101,000 Hz. The EC codes are not compromised by the value of the first 3 bits of the transmitted frequencies as only the value of the 3 most significant bits is utilized in the counting process. This modification defines the limits of circuit errors in the first 3 bits of the signal that are not included in final display indications. At Pin 35 mid-range SF 135,540 Hz, the invention can tolerate errors of +459 or −540 pulses; values outside this range will alter the code and cause incorrect readings. This range relates to Crystal Oscillator 31 FIG. 2 frequency stability and temperature variations and to integrated circuits employed in the design, all of which are extremely accurate and lie well within the tolerable range for errors.

Another improvement over prior art in an embodiment of the present invention is to increase to maximum theoretical scan speed of Transmitter 11 FIG. 1. Counter 34 FIG. 2 now counts to 1,000 Hz producing a 1 ms scan time instead of 10 ms as described above. Thus 168 pulses at Receiver 12 FIG. 4 Pin 68 will be counted during Count Window 81 FIG. 5 instead of 1680 pulses. This modification scans 68 straight-through conductors in Cable 30 FIG. 1 in 0.068 seconds instead of 0.68 seconds.

Testing of multi-conductor cables is not limited to testing all the conductors in the cable. Keypad 20 FIG. 1 operator input can also be a number less than the maximum number of Cable 30 FIG. 1 conductors connected, a range of conductors or even a particular conductor number. The operator may also test unmatched connectors at the ends of a cable by inputting the number of pins connected to Receiver 12 FIG. 1, regardless of the number of pins in the connector at Transmitter 11 FIG. 1. Individual non-terminated wires may also be tested by connecting to Transmitter 11 and Receiver 12, Connectors 26 and 27, respectively, cable adaptors with configurations of mating connectors at one end and of “bed of nails” alligator clip type connectors at the other end.

Referring now to FIG. 1 to operate the apparatus, simply connect one end of a terminated Cable 30 to be tested, say 68 conductors, to Transmitter 11. The apparatus can be powered either by internal battery or by connecting an external power supply. At the transmitter, press the ‘On PB’ and the ‘On Led’ will indicate the unit is activated. ‘Off PB’ turns the unit off. Prior to testing, select ‘Lamp Test PB’ to verify that all display Leds are active. To perform a transmitter self-test, press the ‘Test PB’ and ‘Test Led’ will indicate in the test mode. To select speed of scanning through 68 Fault Leds, select either ‘Run, Slow or Step PBs with their respective indicating Leds. Run mode scans through 68 conductors in 0.68 seconds, Slow mode scans in 13 seconds for visual indications, and Step mode allows the operator to manually scan through. One Led lit, say Led 68 lit, indicates which conductor number is being tested for shorts, but two or more Leds lit will indicate shorts in those numbered conductors, i.e. Led 68, Led 35 and Led 2 lit indicate that conductor 68 is shorted to 35 and 2. The scan will stop to allow the operator to note the error and ‘Ack PB’ resumes the scan until all conductors have been tested. ‘Reset and Hold PBs’ allow for resetting out of the Test mode, and Holding the scan respectively. After the self-test, select ‘Transmit PB’ with ‘Transmit Led’ lit for normal cable testing. Select ‘Run PB’ with ‘Run Led’ lit to transmit sequential frequencies in 0.68 ms in repeat mode. For testing fiber cables also, select ‘Fiber PB’ with “Fiber Led’ lit.

The same operator then connects the other end of test Cable 30 to Receiver 12 as only one person is needed to test cables. The receiver also contains ‘On, Off, Reset, Ack and Lamp Test PBs with their respective Leds that function in exact manner as described above for the Transmitter 11. In the ‘On’ mode, after performing a ‘Lamp Test’ to verify all Leds active, input the number 68 on Keypad 20 corresponding to the number of conductors in the test cable. Error Circuits 82 FIG. 4 will respond if the inputted number is not entered properly or is outside of preprogrammed limits. After confirmation of an acceptable number, select ‘Preset PB’ that records the selected number on LCD Display 18 indicating that the receiver is now monitoring Pin 68 and hence Conductor 68. Two options are now available, either ‘Auto PB’ or ‘Manual PB.’ If ‘Manual PB’ is selected then select ‘Step PB’ and the operator may scan down through 68 sequential steps to test the entire cable. The other option is to select ‘Auto PB’ and then either ‘Fast PB’ or ‘Slow PB’. In the Fast mode the receiver will test all 68 conductors in 0.68 seconds, or in the Slow mode in 13 seconds for visual indication. The final selection is to select ‘Run PB’ to start the test to automatically scan all 68 pins. If all 68 conductors are wired straight-through, then the display will sequentially indicate matching numbers 68-68 down to 01-01, implying no errors in the test. If however the display reads 67-68 indicating Transmitter Pin 67 cross-wired to Receiver 12 Pin 68, then scanning will stop and the operator must acknowledge with ‘Ack PB’ before resuming the test. If perhaps Receiver 12 Pin 68 is also shorted with Pins 13 and 6, then Led 13 and 6 on Display 21 will also be lit indicating the short condition.

It is another object of this invention to provide an improved cable testing apparatus that is portable and reliable for use in final checkout procedures. The apparatus described uniquely displays the relationship between Transmitter 11 generated frequencies, sequentially energized pins and connected conductors, to Receiver 12 sequential pin numbers and connected conductors. It therefore affords a complete mapping of both ends of the terminal connections of Cable 30 under test. This apparatus is unique from all other prior art.

The description of the invention circuitry and drawings as illustrated are partial, as other minor supporting elements in the CPLD devices, discrete IC components and drawings are incorporated in the design. As a preferred cable testing system shown and described, it is envisioned that those skilled in the art may devise various modifications and substitutions or devise new methods of testing. Many other embodiments will be apparent to those of skill in the art upon reviewing the above description, such as, but not limited to, incorporating Graphic Displays and/or Computer Printer outputs, without departing from the spirit thereof. Accordingly, it is to be understood that the present invention has been described by way of illustration and not limitation. The scope of the invention should, therefore, be determined with reference to the appended claims, along with the full scope of equivalents to which such claims are entitled.

1. A portable electronic cable tester apparatus for testing conductors in multi-conductor cables, transmitter means for generation of coded frequency signals applied sequentially to the first end of said cables, receiver means for processing coded frequency signals received sequentially at the second end of said cables, affixed connector means for connecting the first and second ends of said cables to said transmitter means and to said receiver means respectively.

2. Apparatus as claimed in claim 1 wherein said transmitter and said receive means housed in self-contained enclosures consisting of, but not limited to:
(a) Complimentary Metal Oxide Semiconductor (CMOS) electrical components and Complex Programmable Logic (CPLD) devices;
(b) Affixed (n) cable connectors;
(c) Keypad mounted on said enclosures for operator input of control signals;
(d) Printed circuit board for electrical components.

3. A portable electronic cable tester apparatus as claimed in claim 1 wherein:
said transmitter means includes (n) outputs for testing cables having up to (m) separate conductors plus shield (n=m+1), and said receiver means includes (n) separate inputs for receiving (n) signals from said transmitter.

4. A portable electronic cable tester apparatus as claimed in claim 1 wherein:
said transmitter and said receiver affixed connector classes to accept, but not limited to, multi-conductor, telephone, fiber optic and axial type cables.

5. A portable electronic cable tester apparatus as claimed in claim 1 wherein:
means for testing conductor continuity, open or grounded circuits, crossed conductors, short circuits, rolls between pairs, and split pairs.

6. A portable electronic cable tester apparatus as claimed in claim 1 wherein: said apparatus requires the number of conductors in said multi-conductor cables tested to be greater than one (1).

7. A portable electronic cable tester apparatus as claimed in claim 1 wherein: said apparatus means generates Lock Detection Marker, LDM, signal for said transmitter and said receiver synchronization.

8. A portable electronic cable tester apparatus for testing conductors in multi-conductor cables, transmitter means for generation of coded frequency signals applied sequentially to the first end of said cables, receiver means for processing coded frequency signals received sequentially at the second end of said cables, affixed connector means for connecting the first and second ends of said cables to said transmitter means and to said receiver means respectively, wherein:
said CPLD device (n) signal ports to be in the I/O configuration of high input impedance in the input mode and of low output impedance in the output mode.

9. A portable electronic cable tester apparatus as claimed in claim 8 wherein:
said transmitter generates sequential frequencies containing embedded codes in the 5th and 4th bit positions of the decimal value.

10. A portable electronic cable tester apparatus as claimed in claim 8 wherein:
said frequency embedded codes synchronized directly to corresponding numbered said transmitter connector pins and to said affixed cable conductors.

11. A portable electronic cable tester apparatus as claimed in claim 8 wherein:
said generated sequential frequencies contain separation values of (n) KHz.

12. A portable electronic cable tester apparatus as claimed in claim 8 wherein:
said LDM signal is transmitted with each said sequentially generated frequency.

13. A portable electronic cable tester apparatus as claimed in claim 8 wherein:
said transmitter means performs self-test to determine short circuits in the first conductor end of said cables.

14. A portable electronic cable tester apparatus for testing conductors in multi-conductor cables, transmitter means for generation of coded frequency signals applied sequentially to the first end of said cables, receiver means for processing coded frequency signals received sequentially at the second end of said cables, affixed connector means for connecting the first and second ends of said cables to said transmitter means and to said receiver means respectively, wherein:
said transmitted sequential frequencies SF, of (f down-to (a)), contain embedded codes EC, of (e down-to 01), in the 5th and 4th bit positions of the decimal value of said frequencies, applied sequentially to said connector pins Pin, of (p down-to 01), affixed to conductors C, of (c down-to 01).

15. A portable electronic cable tester apparatus as claimed in claim 14 wherein:
said receiver processes said transmitted sequential frequencies, SF of (f down-to (a)), containing embedded codes EC, of (e down-to 01), in the 5th and 4th bit positions of the decimal value of said frequencies, received sequentially at said connector pins Pin, of (p down-to 01) of said conductors C, of (c down-to 01).

16. A portable electronic cable tester apparatus as claimed in claim 14 wherein:
said transmitter scans sequential frequencies SF, of (f down-to (a)), in (n) milliseconds per scan, in (t) seconds per repeating scan cycle.

17. A portable electronic cable tester apparatus as claimed in claim 14 wherein:
said transmitter and said receiver ground return resistors R, of (r down-to 01), connected to said affixed connector pins Pin, of (p down-to 01).

18. A portable electronic cable tester apparatus as claimed in claim 14 wherein:
said receiver is operator inputted the number of said cable conductors C(c), visually displayed through keypad entry.

19. A portable electronic cable tester apparatus as claimed in claim 14 wherein:
said receiver sequentially generates count window (CW) pulse of 1 ms duration, counts received sequential frequencies SF, of (f down-to (a)) during said CW, and visually displays the 5th and 4th bits of said generated frequencies.

20. A portable electronic cable tester apparatus as claimed in claim 14 wherein:
said receiver sequentially compares said count window (CW) pulse numeric containing said transmitter frequency embedded codes EC, of (e down-to 01), with said monitored conductors C, of (c down-to 01), visually displays either affirming signals if said embedded codes in said count window match in number said conductors, or generates error signals if mismatched.
